(19) United States
(12) Patent Application Publication
(10) Pub. No.: US 2013/0249582 A1
(43) Pub. Date: Sep. 26, 2013

(54) AUXILIARY ELEMENT OF PRINTED CIRCUIT BOARD MODULE

(71) Applicants: Hong Fu Jin Precision Industry (Shenzhen) Co., Ltd., (US); HON HAI PRECISION INDUSTRY CO., LTD., New Taipei (TW)

(72) Inventors: YU SHI, Shenzhen (CN); JIE LI, Shenzhen (CN)

(73) Assignees: Hon Hai Precision Industry Co., Ltd., New Taipei (TW); Hong Fu Jin Precision Industry (Shenzhen) Co., Ltd, Shenzhen (TW)

(21) Appl. No.: 13/738,188

(22) Filed: Jan. 10, 2013

(30) Foreign Application Priority Data
Mar. 20, 2012 (CN) 201220105799.7

(51) Int. Cl. G01R 1/04

(52) U.S. Cl. CPC G01R 1/0408
USPC 324/750.25

(57) ABSTRACT

An auxiliary element of a printed circuit board defining a plurality of vias with different shapes and sizes includes a test board defining a plurality of test holes with different shapes and sizes. The test holes of the test board are to have the same shape and size as corresponding vias of the printed circuit board.

### BACKGROUND

1. Technical field

The disclosure generally relates to auxiliary elements of printed circuit boards, and particularly to an auxiliary element of a printed circuit board to be measured.

2. Description of the Related Art

Many printed circuit boards (PCB) define a plurality of different sized vias. As part of quality testing of mass produced PCBs, a certain number of PCBs may need to be cut to expose cross sections of the vias to be measured. The PCBs checked in this manner are damaged beyond repair and cannot be used.

Therefore, there is room for improvement within the art.

### BRIEF DESCRIPTION OF THE DRAWINGS

Many aspects of an exemplary auxiliary element can be better understood with reference to the following drawings. The components in the drawings are not necessarily drawn to scale, the emphasis instead being placed upon clearly illustrating the principles of the exemplary auxiliary element. Moreover, in the drawings, like reference numerals designate corresponding parts throughout the several views. Wherever possible, the same reference numbers are used throughout the drawings to refer to the same or like elements of an embodiment.

FIG. 1 is a schematic view of an auxiliary element of a printed circuit board, according to an exemplary embodiment.

FIG. 2 is a cross section of the auxiliary element shown of FIG. 1 taken along line II-II.

FIG. 3 is a schematic view illustrating specifications of test holes of the auxiliary element shown in FIG. 1.

### DETAILED DESCRIPTION

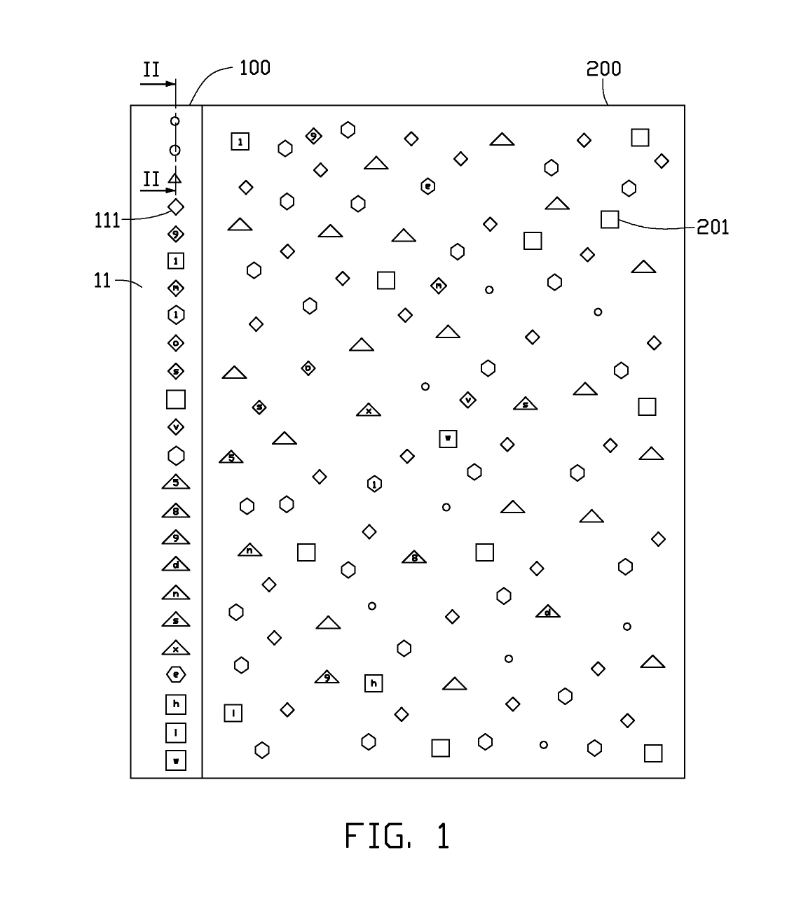

FIG. 1 shows an auxiliary element 100 of a printed circuit board (PCB) 200 defined a plurality of vias 201, according to an exemplary embodiment. The vias 201 are of different shapes and sizes, for example, one such via 201 may have a diameter of 10±3 mils (1 mil=0.001 inch), and another via 201 may have a diameter of 35±3 mils.

The auxiliary element 100 includes a test board 11. The test board 11 can be may be an integral part of the PCB 200 or a separate part but produced together with the PCB 200. In this embodiment, the test board 11 is integral with the PCB 200 and is located at a side of the PCB 200. The test board 11 defines a plurality of test holes 111 with different shapes and sizes, which correspond to the vias 201. Each unique size and shape of the vias 201 have a corresponding test hole 111 in the test board 11. That is the holes 111 are made in the same way as the vias are made, so that if any holes 111 are found to be out of spec then it is known that the corresponding vias 201 are out of spec as well. If no holes 111 are out of spec for a certain PCB 200, then that PCB 200 is proven qualified without destructive testing.

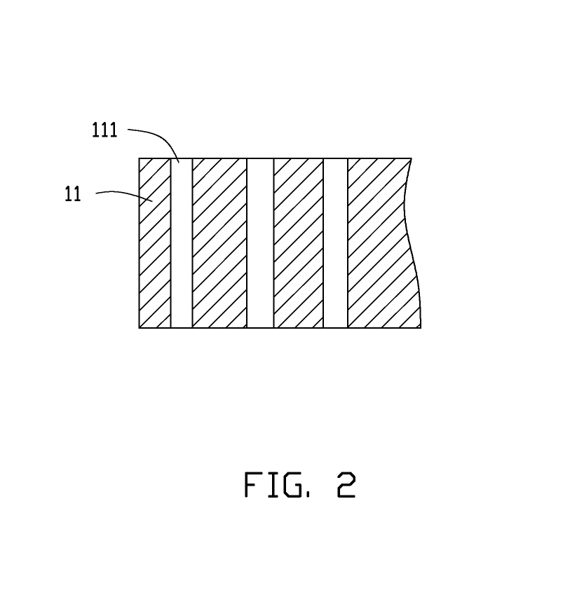

Also referring to FIG. 2, the auxiliary element 100 functions as follows:

The test board 11 is separated from the PCB 200 and is cut to expose cross sections of the test holes 111 to be measured. The test board 11 is cut by a cutting tool (not shown), for example, a knife. The test holes 111 are measured using a measuring tool (not shown), such as a micrometer.

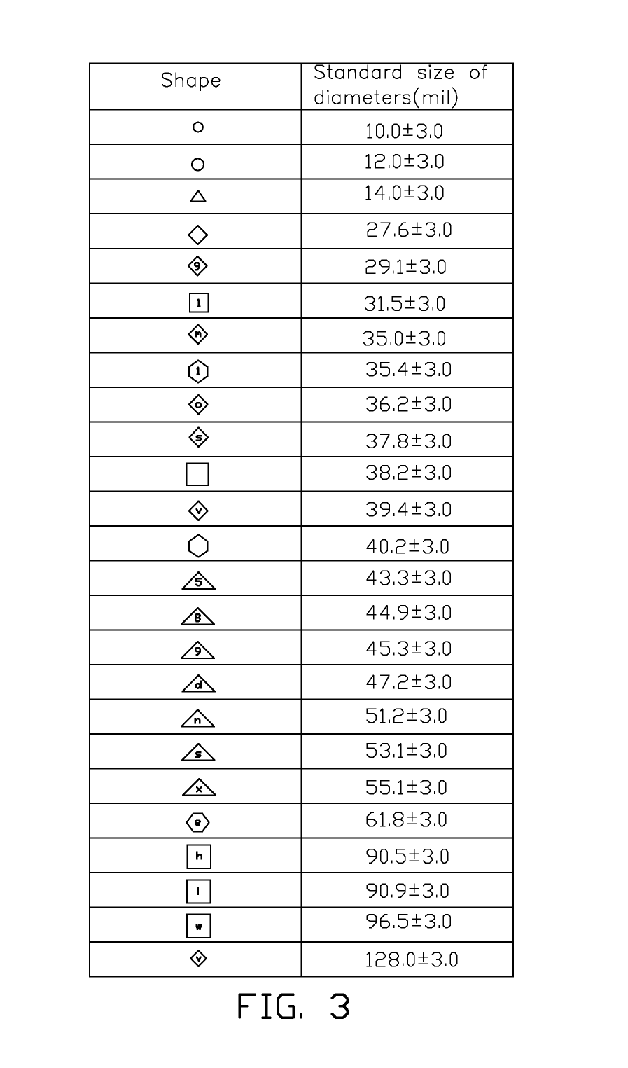

Referring to FIG. 3, a size specification of the test holes 111 is shown. If a triangle-shaped test hole 111 has a measured diameter of 12 mils, and the spec 14.0±3.0 mils in FIG. 2, the triangle-shaped test hole 111 and its corresponding vias 201 are qualified.

The test board 11 defines the plurality of test holes 111 with different shapes and sizes. The vias 201 of the same shape and size correspond to one of the plurality of test holes 111 having the same shape and size as the vias 20. The test board 11 is cut to measure sizes of the test holes 111, if the test holes 111 are qualified, the corresponding vias 201 are qualified. There is no damage to the PCB 200 during the measuring process.

It is to be understood, however, that even though numerous characteristics and advantages of the exemplary disclosure have been set forth in the foregoing description, together with details of the structure and function of the exemplary disclosure, the disclosure is illustrative only, and changes may be made in detail, especially in matters of shape, size, and arrangement of parts within the principles of exemplary disclosure to the full extent indicated by the broad general meaning of the terms in which the appended claims are expressed.

What is claimed is:

1. An auxiliary element of a printed circuit board defining a plurality of vias with different shapes and sizes, the auxiliary element comprising:
a test board defining a plurality of test holes with different shapes and sizes;
wherein the test holes of the test board are to have the same shape and size as corresponding vias of the printed circuit board.

2. The auxiliary element as claimed in claim 1, wherein the test board is cut to expose the cross sections of the test holes for measurement thereof.

3. The auxiliary element as claimed in claim 2, wherein a diameter of the test hole is measured and is compared with a standard diameter, if the test hole is qualified, the corresponding vias of the printed circuit board are qualified.

4. The auxiliary element as claimed in claim 2, wherein the test board is located at a side of the printed circuit board.

5. An auxiliary element of a printed circuit board defining a plurality of vias with different shapes and sizes, the auxiliary element comprising:
a test board defining a plurality of test holes with different shapes and sizes;
wherein each of the plurality of test holes is to have the same shape and size with a plurality of corresponding vias of the printed circuit board.

6. The auxiliary element as claimed in claim 5, wherein the test board is cut to expose the cross sections of the test holes for measurement thereof.

7. The auxiliary element as claimed in claim 6, wherein a diameter of the test hole is measured and is compared with a standard diameter, if the test hole is qualified, the corresponding vias of the printed circuit board are qualified.

8. The auxiliary element as claimed in claim 6, wherein the test board is located at a side of the printed circuit board.

9. A printed circuit board module comprising:
a printed circuit board defining a plurality of vias with different shapes and sizes; and
a test board formed at a side of the printed circuit board, the test board defining a plurality of test holes with different shapes and sizes;
wherein the test holes of the test board are to have the same shape and size as corresponding vias of the printed circuit board.

10. The printed circuit board module as claimed in claim 9, wherein the test board is cut to expose the cross sections of the test holes for measurement thereof.

11. The printed circuit board module as claimed in claim 10, wherein a diameter of the test hole is measured and is compared with a standard diameter, if the test hole is qualified, the corresponding vias of the printed circuit board are qualified.
